(19) United States
(12) Patent Application Publication
(10) Pub. No.: US 2026/0365918 A1
(43) Pub. Date: Nov. 19, 2026

(54) QUANTUM DOT LIGHT EMITTING MATERIAL, QUANTUM DOT LIGHT EMITTING DEVICE AND DISPLAY APPARATUS INCLUDING THE SAME

(71) Applicant: SAMSUNG ELECTRONICS CO., LTD., Suwon-si (KR)

(72) Inventors: Daehee LEE, Suwon-si (KR); Yuho WON, Suwon-si (KR); Jina KIM, Suwon-si (KR); Kwanghee KIM, Suwon-si (KR)

(73) Assignee: SAMSUNG ELECTRONICS CO., LTD., Suwon-si (KR)

(21) Appl. No.: 19/726,249

(22) Filed: Jun. 30, 2026

Related U.S. Application Data
(63) Continuation of application No. PCT/KR2026/095423, filed on Apr. 2, 2026.

(30) Foreign Application Priority Data
Apr. 2, 2025 (KR) 10-2025-0043150

(51) Int. Cl. C09K 11/70; C09K 11/02; C09K 113/00; H10K 50/115; H10K 59/30

(52) U.S. Cl. CPC C09K 11/703; C09K 11/025; H10K 50/115; H10K 59/30; C09K 2113/00

(57) ABSTRACT

A display apparatus may include a plurality of first quantum dots configured to emit red light upon application of current, and a plurality of second quantum dots configured to emit blue light upon application of current. A plurality of ligands are bound to each of the plurality of first quantum dots and the plurality of second quantum dots, and the plurality of ligands may include a first ligand having a first chain and including a carboxyl group, and a second ligand having a second chain shorter than the first chain and including a thiol group. A ratio of a molar content of the second ligand to a molar content of the first ligand, is greater than a ratio of the molar content of the second ligand to the molar content of the first ligand, among the plurality of ligands bound to the plurality of second quantum dots.

### CROSS-REFERENCE TO RELATED APPLICATIONS

This application is a continuation application of International Patent Application No. PCT/KR2026/095423, filed on Apr. 2, 2026, which claims priority to Korean Patent Application No. 10-2025-0043150, filed on Apr. 2, 2025, in the Korean Intellectual Property Office, the disclosures of which are incorporated herein by reference in their entireties.

### TECHNICAL FIELD

The present disclosure relates to a quantum dot light emitting material, a quantum dot light emitting device, and a display apparatus including the same, and more particularly, to a light emitting material including quantum dots bound to heterogeneous ligands, a quantum dot light emitting device, and a display apparatus including the same.

### BACKGROUND ART

Quantum dots (QDs) are inorganic semiconductor nanoparticles that are attracting attention as light emitting materials for next-generation displays due to advantages such as excellent color purity, high quantum efficiency, and applicability to solution processes. In particular, QD-EL (Quantum Dot-Electroluminescent), which is a current-driven quantum dot light emitting device, has a structure in which an emitting layer and an electrode layer are stacked on a glass substrate, and has advantages of a simple structure and excellent image quality because no external light source is required.

Currently, quantum dots used in the emitting layer of QD-EL devices generally include oleic acid (OA) on the surface thereof. However, because oleic acid has weak binding force with quantum dots, it shows poor thermal stability, and a thin film heat treatment process during device fabrication leads to a significant decrease in luminous efficiency.

To solve these problems, research on ligand modification of quantum dot surfaces has recently been actively conducted, and in particular, attempts are being made to improve the stability and light emission properties of quantum dots by introducing various ligands in addition to oleic acid.

### SUMMARY

The present disclosure is directed to providing a quantum dot light emitting material, a quantum dot light emitting device, and a display apparatus including the same, in which the binding ratio of heterogeneous ligands is controlled so that emission efficiency and stability for each emission color are improved.

The technical problems to be addressed by the present disclosure are not limited to those mentioned above, and other technical problems will be apparent to those skilled in the art from the following description.

In one or more embodiments of the present disclosure, a display apparatus may include: at least one first quantum dot light emitting device including a plurality of first quantum dots configured to emit red light upon application of current; and at least one second quantum dot light emitting device including a plurality of second quantum dots configured to emit blue light upon application of current, wherein a plurality of ligands are bound to each of the plurality of first quantum dots and the plurality of second quantum dots, and the plurality of ligands may include: a first ligand having a first chain and including a carboxyl group; and a second ligand having a second chain shorter than the first chain and including a thiol group, and a first ratio, defined as a ratio of a molar content of the second ligand to a molar content of the first ligand, among the plurality of ligands bound to the plurality of first quantum dots is greater than a second ratio, defined as a ratio of the molar content of the second ligand to the molar content of the first ligand, among the plurality of ligands bound to the plurality of second quantum dots.

In one or more embodiments of the present disclosure, a quantum dot light emitting material may include: a plurality of first quantum dots configured to emit red light upon application of current or a plurality of second quantum dots configured to emit blue light upon application of current; and a plurality of ligands bound to a surface of each of the plurality of first quantum dots and plurality of second quantum dots. The plurality of ligands may include: a first ligand having a first chain and including a carboxyl group; and a second ligand having a second chain shorter than the first chain and including a thiol group. A first ratio, defined as a ratio of the molar content of the second ligand to a molar content of the first ligand, among the plurality of ligands bound to the plurality of first quantum dots is greater than a second ratio, defined as a ratio of a molar content of the second ligand to the molar content of the plurality of first ligand, among the plurality of ligands bound to the second quantum dots.

In one or more embodiments of the present disclosure, a display apparatus may include: a first quantum dot configured to emit light in a first wavelength band, a second quantum dot configured to emit light in a second wavelength band, wherein a plurality of ligands are bound to a surface of each of the first quantum dot and the second quantum dot, the plurality of ligands may include: a first ligand including a first chain having 18 or more carbon atoms and including a carboxyl group; and a second ligand including a second chain having 6 to 12 carbon atoms and including a thiol group; and wherein a first ratio, defined as a molar content of the second ligand relative to a molar content of the first ligand on the first quantum dot, is greater than a second ratio, defined as a molar content of the second ligand relative to a molar content of the first ligand on the second quantum dot.

### BRIEF DESCRIPTION OF DRAWINGS

The above and/or other aspects will be more apparent by describing certain example embodiments, with reference to the accompanying drawings.

FIG. 1 is a cross-sectional view showing a part of a cross-section of a display apparatus according to an embodiment of the present disclosure.

FIG. 2 is a cross-sectional view schematically illustrating a cross-section of the light emitting device shown in FIG. 1.

FIG. 3A is a schematic diagram briefly showing the structure of a first quantum dot.

FIG. 3B is a schematic diagram briefly showing the structure of a second quantum dot.

FIG. 4 is a graph showing weight change curves of the first quantum dot according to an embodiment of the present disclosure, as a function of temperature.

FIG. 5 is a graph showing HOD results of the first quantum dot according to an embodiment of the present disclosure.

FIG. 6 is a graph showing external quantum efficiency (EQE) of the first quantum dot according to an embodiment of the present disclosure.

FIG. 7A is a graph showing a weight change curve of the second quantum dot according to an embodiment of the present disclosure, as a function of temperature.

FIG. 7B is a graph showing a weight change curve of the second quantum dot according to an embodiment of the present disclosure, as a function of temperature.

FIG. 7C is a graph showing a weight change curve of the second quantum dot according to a comparative example of the present disclosure, as a function of temperature.

### DETAILED DESCRIPTION

Various embodiments of the present disclosure and terms used herein are not intended to limit technical features disclosed herein to particular modes of practice, and it is to be appreciated that all changes, equivalents, and substitutes of the embodiments are encompassed in the present disclosure.

Regarding the description of the drawings, like reference numerals may be used for like or related elements throughout the drawings.

The singular form of a noun corresponding to an item may include one or more items unless the context states otherwise.

Throughout the specification, “A or B”, “at least one of A and B”, “at least one of A or B”, “A, B or C”, “at least one of A, B and C”, and “at least one or A, B, or C” may each include any one or all the possible combinations of A, B and C.

The term “and/or” is interpreted to include a combination or any of associated elements.

Terms such as “first” or “second” are used to distinguish one component from other components and, therefore, the components are not limited by the terms in any other aspect (e.g., importance or order).

Also, the terms used throughout the specification ‘front’, ‘rear’, ‘top’, ‘bottom’, ‘side’, ‘left’, ‘right’, ‘upper’, ‘lower’, and the like are defined based on the drawings and the shape and position of each element are not limited by these terms.

In addition, the terms such as “including” or “having” are intended to indicate the existence of features, numbers, processes, operations, components, parts, or combinations thereof disclosed in the specification, and are not intended to preclude the possibility that one or more other features, numbers, processes, operations, components, parts, or combinations thereof may exist or may be added.

When an element is mentioned as being “connected to”, “coupled to”, “supported by”, or “contacting” another element, it includes not only a case that the elements are directly connected to, coupled to, supported by or contact each other but also a case that the elements are connected to, coupled to, supported by or contact each other through a third element.

When an element is mentioned as being located “on” another element, it implies not only that the element is in direct contact with the other element but also that a third element exists between the two elements.

In the present disclosure, the term “an embodiment” is intended to encompass one or more embodiments, rather than being limited to a single example. Furthermore, features described in embodiments may be combined and implemented together.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, embodiments according to the present disclosure will be described in detail with reference to the accompanying drawings.

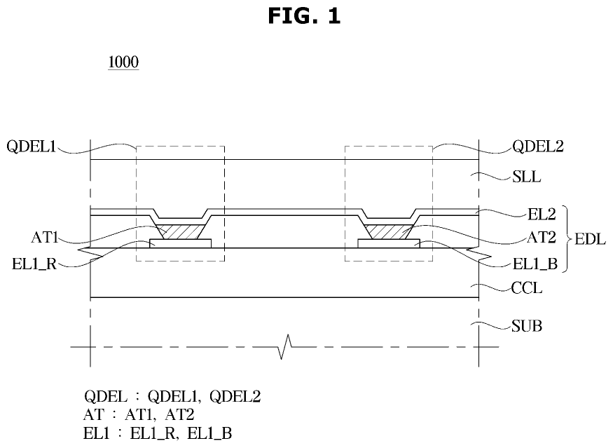

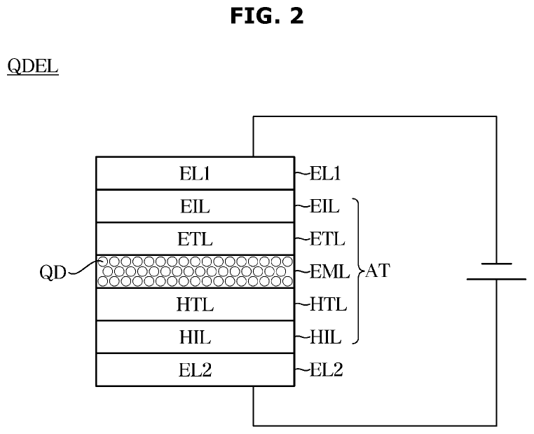

FIG. 1 is a cross-sectional view showing a part of a cross-section of a display apparatus according to an embodiment of the present disclosure. FIG. 2 is a cross-sectional view schematically illustrating a cross-section of the light emitting device shown in FIG. 1.

Referring to FIGS. 1 and 2, a display apparatus 1000 according to an embodiment of the present disclosure may be an apparatus for displaying images, video, or text. That is, the display apparatus 1000 may include a display panel configured to emit light upon application of current.

The display apparatus 1000 may be used not only for large electronic devices such as monitors or external billboards, but also for medium and small electronic devices such as personal computers, notebook computers, personal digital assistants, automobile navigation units, game machines, smartphones, tablets, and cameras, and may also be employed in home appliances such as refrigerators, washing machines, and vacuum cleaners.

A display apparatus 1000 according to an embodiment of the present disclosure may include a plurality of pixels configured to emit light upon application of current. The pixels are disposed on a substrate SUB to constitute the display panel. An area on the display panel where the pixels are disposed is defined as a display area, and areas on the display panel where the pixels are not disposed may be defined as non-display areas. Each of the pixels includes the light emitting devices (QDEL).

Specifically, the display panel may include a substrate SUB, a circuit layer CCL, a device layer EDL, and an encapsulation layer SLL.

The substrate SUB may include a synthetic resin substrate or a glass substrate. Embodiments of the present disclosure are not limited to the particular size, thickness, and characteristics of the substrate SUB. In the present embodiment, the substrate SUB may have various thicknesses and characteristics depending on the use of the display apparatus and required characteristics.

The circuit layer CCL is formed on the substrate SUB and includes various electrical elements for driving the quantum dot light emitting device QDEL. The circuit layer CCL includes at least one insulating layer, a plurality of conductive layers, and a semiconductor layer. The conductive layers of the circuit layer CCL may constitute signal lines such as data lines, gate lines, and power lines, or a pixel circuit including a transistor for controlling driving of the pixel. The signal lines and the pixel circuit serve to supply electrical signals and current required for the quantum dot light emitting device QDEL.

The device layer EDL is disposed on the circuit layer CCL. The device layer EDL includes a quantum dot light emitting device QDEL as a display element. In the present embodiment, the quantum dot light emitting device QDEL may be a quantum dot light emitting diode that generates light when current is applied. The device layer EDL may include various functional layers assisting the operation of the quantum dot light emitting device QDEL in addition to the quantum dot light emitting device QDEL.

The quantum dot light emitting device QDEL includes a pixel electrode EL1, an active layer AT, and a common electrode EL2.

The pixel electrode EL1 is positioned in a lower portion of the quantum dot light emitting device QDEL and is independently formed for each pixel (see EL1_R, EL1_B). The pixel electrode EL1 is electrically connected to a pixel circuit of the circuit layer CCL and serves to drive individual pixels. In the present embodiment, the pixel electrode EL1 may be an anode. The pixel electrode EL1 may be connected to a positive power source and may serve to inject holes into the active layer AT.

The common electrode EL2 is positioned in an upper portion of the quantum dot light emitting device QDEL and may be commonly formed for a plurality of pixels. In the present embodiment, the common electrode EL2 may be a cathode. The common electrode EL2 may be connected to a negative power source to inject electrons into the active layer AT.

The active layer AT is disposed between the pixel electrode EL1 and the common electrode EL2. As shown in FIG. 2, the active layer AT may include an electron transfer layer including an electron injection layer EIL and an electron transport layer ETL, a hole transfer layer including a hole transport layer HTL and a hole injection layer HIL, and an emitting layer EML.

The electron injection layer EIL is disposed between the common electrode EL2 and the electron transport layer ETL to facilitate injection of electrons from the common electrode EL2. For example, the electron injection layer EIL may be formed of a material such as lithium fluoride (LiF), calcium fluoride (CaF₂), or lithium oxide (Li₂O).

The electron transport layer ETL is disposed between the electron injection layer EIL and the emitting layer EML to efficiently transport injected electrons to the emitting layer EML. For example, the electron transport layer ETL may be formed of an organic compound such as an aluminum complex or a zinc complex.

The emitting layer EML is disposed between the electron transport layer ETL and the hole transport layer HTL and includes quantum dots QD. The emitting layer EML may emit light by recombination of electrons and holes. In the present disclosure, the quantum dots QD may be bound to heterogeneous ligands having a carboxyl group and a thiol group.

The hole transport layer HTL is disposed between the emitting layer EML and the hole injection layer HIL to efficiently transport injected holes to the emitting layer. For example, the hole transport layer HTL may be formed of an organic compound such as a triphenylamine derivative or a carbazole derivative.

The hole injection layer HIL is disposed between the pixel electrode EL1 and the hole transport layer HTL to facilitate injection of holes from the pixel electrode EL1. For example, the hole injection layer HIL may be formed of a material such as molybdenum oxide (MoO₃) or tungsten oxide (WO₃).

In the present disclosure, materials included in each of the electron transport layer ETL, the electron injection layer EIL, the hole transport layer HTL, and the hole injection layer HIL are not particularly limited.

According to an embodiment of the present disclosure, each of the plurality of light emitting devices QDEL included in the display apparatus 1000 may emit light in different wavelength bands. Specifically, the plurality of light emitting devices QDEL may include a first quantum dot light emitting device QDEL1 and a second quantum dot light emitting device QDEL2.

The first quantum dot light emitting device QDEL1 may include a first pixel electrode EL1_R, a first active layer AT1, and a common electrode EL2, and the first active layer AT1 may include first quantum dots QD1 that emit red light. The quantum dots included in the first emitting layer EML of the first active layer AT1 may be the first quantum dots QD1.

According to an embodiment of the present disclosure, the quantum yield (QY) of the first quantum dots QD1 may be 90% or more, and the external quantum efficiency (EQE) of the first quantum dot light emitting device QDEL1 may be 13% or more.

The second quantum dot light emitting device QDEL2 may include a second pixel electrode EL1_B, a second active layer AT2, and a common electrode EL2, and the second active layer AT2 may include second quantum dots QD2 that emit blue light. That is, the quantum dots included in the second emitting layer EML of the second active layer AT2 may be the second quantum dots QD2.

According to an embodiment of the present disclosure, the quantum yield (QY) of the second quantum dots QD2 may be 95% or more, and the external quantum efficiency (EQE) of the second quantum dot light emitting device QDEL2 may be 5% or more. In addition, the photoluminescence (PL) intensity measured after performing heat treatment on the second quantum dots QD2 at 150 °C for 30 minutes may be 70% or more.

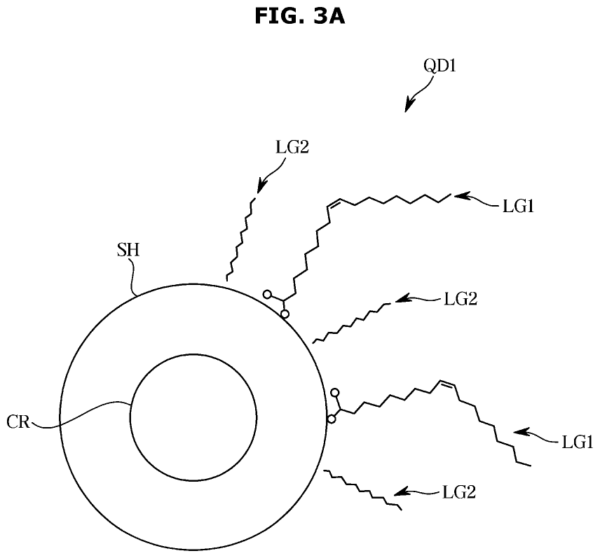

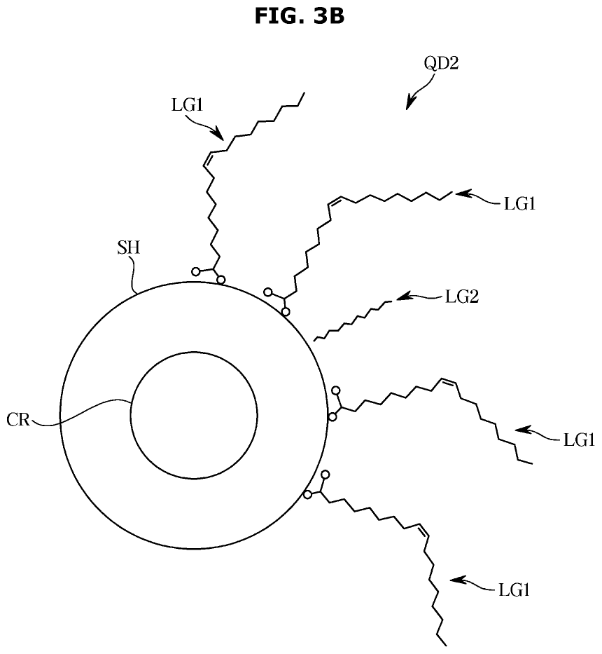

Both the first quantum dots QD1 and the second quantum dots QD2 may be surface-treated with a first ligand LG1 (FIGS. 3A and 3B) including a carboxyl group and a second ligand LG2 (FIGS. 3A and 3B) including a thiol group.

The encapsulation layer SLL is disposed on the upper side of the device layer EDL. The encapsulation layer SLL serves to protect the device layer EDL from the external environment. The encapsulation layer SLL may prevent penetration of moisture and oxygen to prevent deterioration of the quantum dot light emitting device QDEL and extend its lifetime. The encapsulation layer SLL may be composed of an organic material layer, an inorganic material layer, or an alternating layer in which they are alternately stacked. For example, the encapsulation layer SLL may have a thin film encapsulation structure.

FIG. 3A is a schematic diagram briefly showing the structure of a first quantum dot. FIG. 3B is a schematic diagram briefly showing the structure of a second quantum dot.

Referring to FIGS. 3A and 3B, each of the first quantum dot QD1 and the second quantum dot QD2 may have a core-shell structure including a core CR and a shell SH surrounding the core CR.

The core CR may serve as a center of light emission and may determine optical properties of the quantum dots QD1 and QD2. The wavelength of light emitted by the quantum dots QD1 and QD2 may be determined according to the size, composition, and crystal structure of the core CR. For example, the size of the first quantum dot QD1 may be adjusted so that the emission wavelength band has a range of 620 nm to 650 nm, and the size of the second quantum dot QD2 may be adjusted so that the emission wavelength band has a range of 450 to 480 nm. In this case, the size of the second quantum dot may be smaller than the size of the first quantum dot. In the present disclosure, the core CR may be composed of a Group III-V compound such as InP, InZnP, or InGaP, or a Group II-VI compound such as ZnSe, ZnTeSe, or ZnTe.

The shell SH is a protective layer surrounding the core CR. The shell SH may reduce surface defects of the core, protect the core CR from the external environment, and improve the quantum efficiency and stability of the quantum dots. The shell SH may be composed of ZnSe, ZnS, ZnSeS, or a combination thereof, and may be composed of 10 to 20 monolayers. In another embodiment of the present disclosure, the shell SH may be omitted.

According to an embodiment of the present disclosure, the configuration of ligands bound to the surface of each of the first quantum dot QD1 and the second quantum dot QD2 may be different.

Specifically, the plurality of ligands bound to the surface of each of the first quantum dot QD1 and the second quantum dot QD2 may include a first ligand LG1 and a second ligand LG2.

The first ligand LG1 may include a first chain and a carboxyl group (—COOH). In the present embodiment, the first chain may include 18 or more carbon atoms. When the number of carbon atoms is less than 18, the spacing between the quantum dots QD1 and QD2 is not sufficiently maintained, causing aggregation of the quantum dots QD1 and QD2 and a sharp decrease in quantum efficiency. On the other hand, when the number of carbon atoms is 18 or more, an appropriate spacing between the quantum dots QD1 and QD2 is maintained to improve dispersibility and prevent a decrease in quantum efficiency. In the present embodiment, the first ligand LG1 may be oleic acid (OA), which is an unsaturated fatty acid having 18 carbon atoms. Oleic acid may coordinate-bond with metal atoms on the surface of the quantum dots QD1 and QD2 through a carboxyl group.

The second ligand LG2 may include a second chain and a thiol group (—SH). In the present embodiment, the length of the second chain may be shorter than the length of the first chain. Specifically, the number of carbon atoms of the second chain is 6 or more and 12 or less. When the number of carbon atoms is less than 6, the colloidal stability of the quantum dots QD1 and QD2 decreases, causing precipitation in a solution state, and it may be difficult to form a uniform thin film. On the other hand, when the number of carbon atoms exceeds 12, the chain becomes excessively long, reducing the effect of improving hole injection efficiency, and the organic material content increases, which may reduce thermal stability. In the present embodiment, the second ligand LG2 may be dodecanethiol (DDT), which is a straight-chain alkane thiol having twelve carbon atoms.

The length difference between the first chain and the second chain may affect the electrical properties of the quantum dots. Specifically, the length difference between the first chain (18 or more carbon atoms) and the second chain (6 to 12 carbon atoms) determines the length of the path through which charge carriers, particularly holes, approach the quantum dot core CR. It has been observed that when the second chain is shorter than the first chain by at least 6 carbon atoms, hole injection efficiency significantly improves. This is because holes can reach the quantum dot core more rapidly and efficiently through the short chain. Experimental results confirmed that such a difference in chain length plays a role in lowering the driving voltage of the light emitting device and improving external quantum efficiency (EQE).

According to an embodiment of the present disclosure, a first ratio, defined as a ratio of the molar content of the second ligand LG2 to the molar content of the first ligand LG1, among the ligands bound to the first quantum dots QD1 may be greater than a second ratio, defined as a ratio of the molar content of the second ligand LG2 to the molar content of the first ligand LG1, among the ligands bound to the second quantum dots QD2.

The first ratio may range from 1 to 2.5. When the first ratio is less than 1, the effect of improving hole injection efficiency is insignificant and the improvement in luminous efficiency is limited, and when the first ratio exceeds 2.5, the quantum efficiency may rapidly decrease. In a more preferable embodiment, the first ratio may range from 1 to 1.5.

The second ratio may range from 0.25 to 1. When the second ratio is less than 0.25, the emission efficiency (EQE) improvement effect may not appear or may decrease, and when the second ratio exceeds 1, the luminous efficiency may rapidly decrease due to an increase in surface trap states characteristic of blue quantum dots. In a more preferable embodiment, the second ratio may range from 0.28 to 0.53.

In the present embodiment, the reason ligand ratios vary between quantum dots QD1 and QD2 lies in their fundamental differences in the physicochemical properties and light emission mechanisms of the two quantum dots QD1 and QD2. The first quantum dot QD1 has a relatively small emission wavelength band, and thus improvement in hole injection efficiency directly affects improvement in luminous efficiency. Blue quantum dots have a large emission wavelength band and are more sensitive to surface trap states, and thus excessive dodecanethiol treatment may degrade light emission properties. Therefore, in the present embodiment, by applying an optimal ligand ratio for each quantum dot QD1, QD2 in consideration of the characteristic differences by emission color of the quantum dots, the performance of the quantum dot light emitting device may be maximized for each color.

In addition, according to the present embodiment, compared to the case in which only the first ligand LG1 is bound to the quantum dots QD1 and QD2, the thermal stability of the quantum dots QD1 and QD2 may be improved due to the strong binding force of the second ligand LG2. In particular, the photoluminescence intensity of the quantum dots QD1 and QD2 may be maintained at a high level even after heat treatment at 150 °C for 30 minutes. In addition, according to the present embodiment, the hole injection rate may be improved due to the short chain length of the second ligand LG2, thereby increasing the luminous efficiency, and the reduced organic material content may improve the overall stability and lifetime of the quantum dot light emitting device QDEL.

In one or more embodiments, charge transport and stability of a quantum dot light-emitting device (QDEL) may be improved by applying a dual-ligand system with asymmetric ratios tailored to a specific emission color of quantum dots. By utilizing a long-chain carboxyl ligand (e.g., oleic acid) for dispersibility and a shorter-chain thiol ligand (e.g., dodecanethiol) to facilitate rapid hole injection, a display device may achieve higher external quantum efficiency and lower driving voltages. Red quantum dots (QD1) may have a higher ratio of the short-chain thiol ligand to maximize hole injection, whereas blue quantum dots (QD2) have a lower ratio to prevent degradation of luminous efficiency caused by surface trap states.

Hereinafter, the present disclosure will be described in more detail by the following examples. However, the following examples are only for illustrating the present disclosure, and the scope of the present disclosure is not limited thereto.

### EXAMPLES

(1) Quantum Dot Synthesis and Ligand Treatment (Preparation of Light Emitting Material)

First, quantum dots having a core and a shell composed of a Group III-V or Group II-VI semiconductor compound are synthesized. The first quantum dots are synthesized to have an indium phosphide/zinc sulfide (InP/ZnS) core-shell structure, and the second quantum dots are synthesized to have a zinc selenide/zinc sulfide (ZnSe/ZnS) core-shell structure. Initially, the synthesized quantum dots may have only oleic acid (OA) as a ligand.

Thereafter, a heterogeneous ligand treatment are performed by varying the ratio of dodecanethiol (DDT) to OA. For this, DDT is added at different ratios to a quantum dot dispersion in which the surface had been treated with OA, and the mixture is stirred at 30 °C for 12 hours to induce a ligand exchange reaction. After the reaction, an excess amount of acetone is added to precipitate the quantum dots, which are separated or isolated via centrifugation. Thereafter, the quantum dots are redispersed in toluene to obtain a final quantum dot dispersion.

As described in Table 1, in the case of the first quantum dots, the heterogeneous ligand treatment is performed by varying the DDT:OA ratio to 2.33:1 (Inventive Example 1), 1.49:1 (Inventive Example 2), and 1:1 (Inventive Example 3). For Comparative Example 1, quantum dots having only OA as a ligand are prepared, and for Comparative Example 2, quantum dots having a DDT:OA ratio of 0.56:1 are prepared. In Table 1, Inventive Examples 1-3 represent inventive examples according to embodiments of the present disclosure.

TABLE 1

First Ratio

| | DDT | OA |
|---|---|---|
| Comparative Example 1 | 0 | 1 |
| Comparative Example 2 | 0.56 | 1 |
| Inventive Example 1 | 2.33 | 1 |
| Inventive Example 2 | 1.49 | 1 |
| Inventive Example 3 | 1 | 1 |

As described in Table 2, in the case of the second quantum dots, heterogeneous ligand treatment is performed by varying the DDT:OA ratio to 0.53:1 (Inventive Example 4) and 0.29:1 (Inventive Example 5). For Comparative Example 3, quantum dots having only OA as a ligand were prepared, and for Comparative Example 4, quantum dots having a DDT:OA ratio of 0.24:1 were prepared. In Table 1, Inventive Examples 4 and 5 represent inventive examples according to embodiments of the present disclosure.

TABLE 2

Second Ratio

| | DDT | OA |
|---|---|---|
| Comparative Example 3 | 0 | 1 |
| Inventive Example 4 | 0.53 | 1 |
| Inventive Example 5 | 0.29 | 1 |
| Comparative Example 4 | 0.24 | 1 |

### (2) Quantum Dot Light Emitting Device Fabrication

Quantum dot light emitting devices are fabricated with the following structure:

QDEL1 (First Quantum Dot):ITO/HIL/HTL(250 Å)/R-QD(250 Å)/ETL(667 Å)/AL

QDEL2 (Second Quantum Dot):ITO/HIL/HTL(250 Å)/B-QD(250 Å)/ETL(667 Å)/AL

In these structures, ITO represents an indium tin oxide electrode, HIL represents a hole injection layer, HTL represents a hole transport layer, R-QD and B-QD represent red and blue quantum dot layers, respectively, ETL represents an electron transport layer, and AL represents an aluminum electrode. In some experiments, an organic material removal process is additionally performed on the quantum dot layer.

The device fabrication process is as follows. After cleaning an ITO-patterned glass substrate, a hole injection layer and a hole transport layer are sequentially deposited by vacuum thermal evaporation. Thereafter, a quantum dot light emitting material is applied by a spin coating method and dried at 100 °C for 30 minutes. Finally, an electron transport layer and an aluminum electrode are deposited by vacuum thermal evaporation to complete the device.

### (3) Hole-Only Device (HOD) Device Fabrication

A hole-only device (HOD) for evaluating the hole injection and transport characteristics of the first quantum dots is fabricated with the following structure: ITO/HIL/HTL (250 Å)/R-QD (250 Å)/GSH137 (300 Å)/L101 (100 Å)/AL. Here, ITO represents an indium tin oxide electrode, HIL represents a hole injection layer, HTL represents a hole transport layer, R-QD represents a red quantum dot layer, and GSH137 and L101 each represent a hole blocking layer. In this structure, electron injection is limited, allowing evaluation of hole-only injection characteristics.

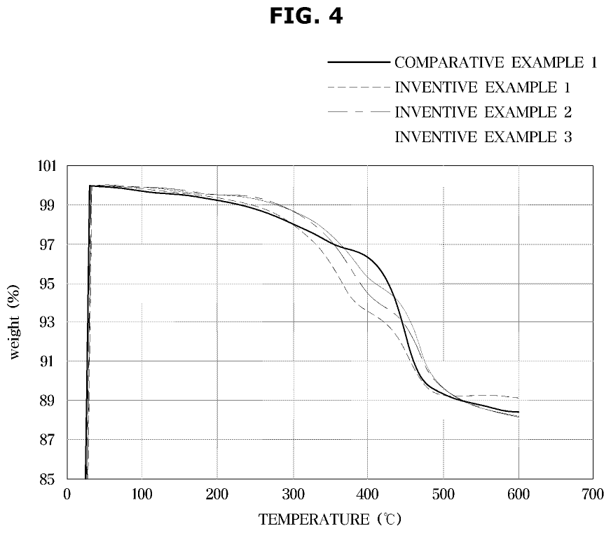

FIG. 4 is a graph showing weight change curves (thermogram) of the first quantum dot as a function of temperature, according to an embodiment of the present disclosure, as a function of temperature.

The weight change curves are obtained using a thermogravimetric analyzer (TGA). For the TGA measurement, about 10 mg of each first quantum dot sample, synthesized with different ligand ratios, is placed in an alumina crucible. Thereafter, the weight change according to temperature is measured while heating samples from 25 °C to 600 °C at a heating rate of 10 °C/min under a nitrogen atmosphere. In these samples, the first ligand is oleic acid and the second ligand is dodecanethiol.

In FIG. 4, the horizontal axis represents temperature (C), the vertical axis represents weight percentage (%), and the weight change curves of Inventive Examples 1 to 3 according to embodiments and Comparative Example 1, each having a different first ratio (the content of DDT relative to OA) are shown.

Inventive Example 1 is a case where the first ratio is 2.33, Inventive Example 2 is a case where the first ratio is 1.49, and Inventive Example 3 is a case where the first ratio is 1. Comparative Example 1 is a case where the first ratio is 0. That is, Comparative Example 1 is a case where only OA is bound to the first quantum dots.

As shown in FIG. 4, examining the weight change around 150 °C reveals that there is a difference in the weight reduction pattern between Inventive Examples 1-3 and Comparative Example 1. The temperature range around 150 °C may be a heat treatment temperature generally applied in the manufacturing process of quantum dot light emitting devices. In FIG. 4, all samples tend to decrease in weight as the temperature increases. This decrease in weight is due to thermal decomposition or desorption of ligands, and the smaller the weight decrease, the better the thermal stability of the quantum dots may be evaluated. In FIG. 4, it can be seen that all of Inventive Examples 1 to 3 have improved thermal stability compared to Comparative Example 1.

Table 3 shows the results of measuring the quantum yield (QY) of Inventive Examples 1 to 3 and Comparative Example 1. Inventive Examples 1-3 are provided according to embodiments of the present disclosure.

The QY is measured using a spectrofluorometer and an integrating sphere. The first quantum dots are dispersed in toluene, irradiated with ultraviolet light of a wavelength of 365 nm, and the emission spectrum is measured. The quantum efficiency is obtained by calculating the ratio of emitted light to incident light.

TABLE 3

| | First Ratio | QY(%) | |
|---|---|---|---|
| | DDT | OA | QY(%) |
| Comparative Example 1 | 0 | 1 | 96 |
| Inventive Example 1 | 2.33 | 1 | 90 |
| Inventive Example 2 | 1.49 | 1 | 96 |
| Inventive Example 3 | 1 | 1 | 96 |

Referring to Table 3, in the case of Inventive Example 1, the quantum efficiency is 90%, which is slightly lower than that of Comparative Example 1, but still maintains excellent light emission properties. Meanwhile, in the cases of Inventive Examples 2 and 3, a high quantum efficiency of 96% is shown, indicating that the quantum efficiency is maintained at a level equivalent to that of Comparative Example 1 while thermal stability is improved.

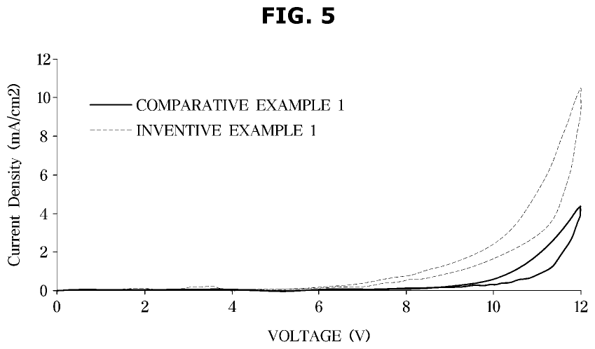

FIG. 5 is a graph showing HOD results of the first quantum dot according to an embodiment of the present disclosure.

A HOD is fabricated to evaluate hole injection and transport characteristics, and a device showing a higher current density at the same voltage indicates superior hole injection characteristics.

The HOD measurement is performed using a sourcemeter. While applying a voltage from OV to 12V to the device, the flowing current is measured, and the current is divided by the effective area of the device to calculate the current density (mA/cm²). Through the current-voltage characteristic curve, the hole injection efficiency may be compared.

In FIG. 5, the horizontal axis represents voltage (V), and the vertical axis represents current density (mA/cm²). In FIG. 5, the HOD characteristics of Inventive Example 1 and Comparative Example 1 are compared. The current density is measured to evaluate the hole transport (HT) capacity of the quantum dots.

As shown in FIG. 5, Inventive Example 1 exhibits a higher current density overall than Comparative Example 1. This can also be confirmed in Table 4 below.

TABLE 4

Current Density (mA/cm²)

| | 8 V | 12 V |
|---|---|---|
| Comparative Example 1 | 0.1 | 4.4 |
| Inventive Example 1 | 0.8 | 10.6 |

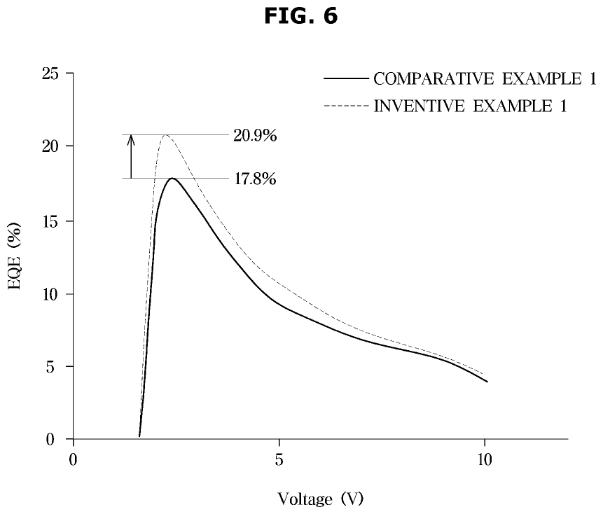

As described in Table 4, the current density of Inventive Example 1 at a voltage of 8V is 0.8 mA/cm², which is eight times the current density of Comparative Example 1 of 0.1 mA/cm². In addition, at a voltage of 12V, the current density of Inventive Example 1 is 10.6 mA/cm², which is about 2.4 times the current density of Comparative Example 1 of 4.4 mA/cm². The above results are because the chain length of the second ligand is shorter than that of the first ligand, lowering the hole injection barrier, and thereby greatly improving the hole injection rate. The improvement in hole injection efficiency may lead to an increase in the overall luminous efficiency of the quantum dot light emitting device, which may also be confirmed in the external quantum efficiency results of FIG. 6 to be described later.

FIG. 6 is a graph showing external quantum efficiency (EQE) of the first quantum dot according to an embodiment of the present disclosure.

The EQE measurement is performed using a calibrated photocurrent measurement system. Specifically, the optical output generated while current is applied to the quantum dot light emitting device is measured with a photodiode, and the EQE is obtained as a ratio of the output to the input current. The EQE is an important indicator for comprehensively evaluating the luminous efficiency of the device.

Referring to FIG. 6, the horizontal axis represents voltage (V), and the vertical axis represents external quantum efficiency (EQE, %). The graph compares the EQE characteristics of Comparative Example 1 (before DDT exchange, first quantum dots with only OA applied) and Inventive Example 1 (after DDT exchange, quantum dots with heterogeneous ligands applied).

As shown in FIG. 6, Inventive Example 1 exhibits a higher EQE overall than Comparative Example 1. This can also be confirmed in Table 5.

TABLE 5

| | | | EQE(%) | |
|---|---|---|---|---|
| | | | Before organic | After organic |
| | First Ratio | | material | material |
| | DDT | OA | removal | removal |
| Comparative Example 1 | 0 | 1 | 17.8 | 12.9 |
| Inventive Example 1 | 2.33 | 1 | 20.9 | — |
| Inventive Example 2 | 1.49 | 1 | — | — |
| Inventive Example 3 | 1 | 1 | — | 15.9 |
| Comparative Example 2 | 0.56 | 1 | — | 11.9 |

As described in Table 5, the maximum EQE of Inventive Example 1 is 20.9%, which is improved by about 3.1% compared to 17.8% for the EQE of Comparative Example 1. In addition, when comparing the EQE after organic material removal, the EQE of Inventive Example 3 is 15.9%, which is improved by 3.0% compared to 12.9% for the EQE of Comparative Example 1. On the other hand, the EQE of Comparative Example 2 is 11.9%, which is decreased compared to Comparative Example 1. These results show that in the case of the first quantum dots, the EQE is improved when the DDT:OA ratio is within an appropriate range. In particular, it can be seen that optimal luminous efficiency may be obtained when the DDT:OA ratio is from 1:1 to 2.33:1.

The EQE improvement may be attributed to the improvement in hole injection efficiency confirmed in FIG. 5 and the increase in luminous efficiency due to the reduction in organic material content. In conclusion, the performance of the light emitting device may be greatly improved by applying heterogeneous ligand treatment to the first quantum dots, which are red emitters.

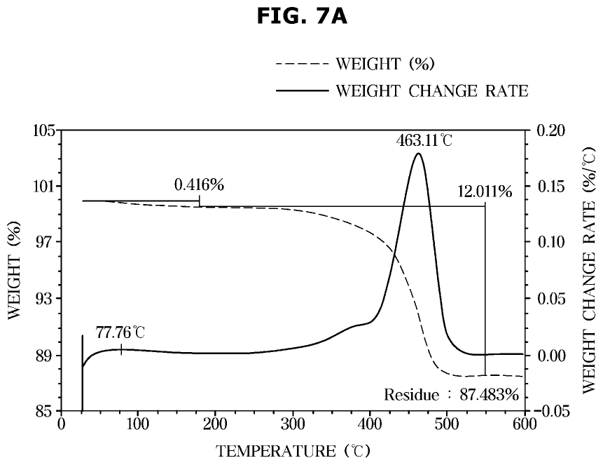

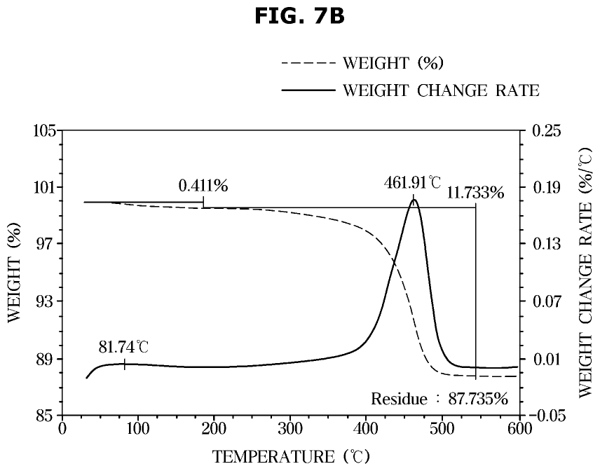

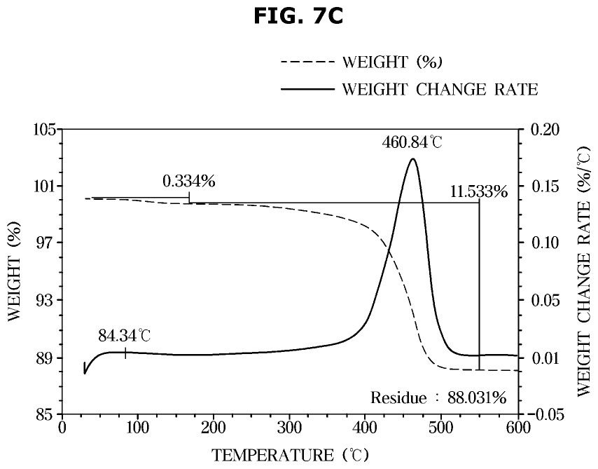

FIGS. 7A and 7B are graphs showing weight change curves the second quantum dot according to an embodiment of the present disclosure, as a function of temperature. FIG. 7C is a graph showing a weight change curve of a second quantum dot according to a comparative example of the present disclosure, as a function of temperature.

The TGA measurement of the second quantum dots, which are blue emitters, is performed in the same manner as the first quantum dots described above. About 10 mg of each second quantum dot (blue emitting) sample synthesized with different ligand ratios (DDT:OA) is placed in an alumina crucible. Thereafter, the weight change according to temperature is measured while heating from 25 °C to 600 °C at a heating rate of 10 °C/min under a nitrogen atmosphere.

Referring to FIGS. 7A to 7C, the horizontal axis represents temperature (°C), and the vertical axis represents weight ratio (%). FIGS. 7A and 7B show weight change curves of examples having different DDT:OA ratios (Inventive Example 4: DDT:OA=0.53:1, Inventive Example 5: DDT:OA=0.29:1), and FIG. 7C shows a weight change curve of Comparative Example 4 (DDT:OA=0.24:1).

Examining the weight reduction rate around 180 °C in the graph, the values are measured to be 0.416% in Inventive Example 4 (FIG. 7A), 0.411% in Inventive Example 5 (FIG. 7B), and 0.334% in Comparative Example 4 (FIG. 7C). These values represent the weight reduction rate at the corresponding temperature. Although Comparative Example 4 shows a slightly lower weight reduction rate in the corresponding temperature region, the overall thermal stability may not be determined only by the weight reduction rate at a single temperature point.

Table 6 below is a table describing the measured QY values of Inventive Examples 4 and 5 and Comparative Example 4.

TABLE 6

| | Second Ratio | | |
|---|---|---|---|
| | DDT | OA | QY(%) |
| Comparative Example 3 | 0 | 1 | — |
| Inventive Example 4 | 0.53 | 1 | 95 |
| Inventive Example 5 | 0.29 | 1 | 95 |
| Comparative Example 4 | 0.24 | 1 | 96 |

As described in Table 6, all samples with heterogeneous ligand treatment (Inventive Examples 4 and 5, Comparative Example 4) maintain a high quantum efficiency of 95-96%. This shows that the DDT:OA heterogeneous ligand treatment may improve thermal stability without degrading the light emission properties of the second quantum dots. For a more comprehensive evaluation of thermal stability, the PL retention rate is measured after heat treatment at 150 °C for 30 minutes.

TABLE 7

PL(%)

| | Before heat | After heat |
|---|---|---|
| | treatment | treatment |
| Comparative Example 3 | 100 | 56.2 |
| Inventive Example 4 | 100 | 84.3 |
| Inventive Example 5 | 100 | — |
| Comparative Example 4 | 100 | 79.8 |

As described in Table 7, the PL retention rate of Comparative Example 3 (only OA applied) is 56.2%, which is the lowest, whereas the PL retention rate of Inventive Example 4 (DDT:OA=0.53:1) is 84.3%, which is the highest. Even in the case of Comparative Example 4 (DDT:OA=0.24:1), the PL retention rate is 79.8%, which is significantly higher than that of Comparative Example 3. This shows that DDT:OA heterogeneous ligand treatment, regardless of a specific ratio of DDT:OA, greatly improves the thermal stability of the second quantum dots compared to the case where only OA is applied.

Table 8 below is a table describing the measured EQE values of the second quantum dots.

TABLE 8

| | EQE(%) |
|---|---|
| Comparative Example 3 | 4.7 |
| Inventive Example 4 | 7.5 |
| Inventive Example 5 | 5.5 |
| Comparative Example 4 | 4.3 |

As described in Table 8, the EQE of Inventive Example 4 is 7.5%, which is improved by 2.8% compared to 4.7% for the EQE of Comparative Example 3. The EQE of Inventive Example 5 is 5.5%, which is improved by 0.8% compared to the EQE of Comparative Example 3. The EQE of Comparative Example 4 is 4.3%, which maintained a level similar to the EQE of Comparative Example 3. When the above results are summarized, it can be seen that by applying the DDT:OA heterogeneous ligands (to the second quantum dots, which are blue emitters, the thermal stability and device luminous efficiency are generally improved while the initial QY is maintained. In particular, when the DDT:OA ratio is 0.53:1 (Inventive Example 4), optimal performance is shown. Although the performance gradually decreases as the ratio deviates from this value, it still maintains superior characteristics compared to the case where only OA is applied. This suggests that in the case of the second quantum dots, the optimal DDT:OA ratio range is between 0.25:1 and 1:1 (corresponding to a second ratio between 0.25 and 1).

In one or more embodiments of the present disclosure, a display apparatus may include: at least one first quantum dot light emitting device including a plurality of first quantum dots configured to emit red light upon application of current; and at least one second quantum dot light emitting device including a plurality of second quantum dots configured to emit blue light upon application of current, wherein a plurality of ligands are bound to each of the plurality of first quantum dots and the plurality of second quantum dots, and the plurality of ligands may include: a first ligand having a first chain and including a carboxyl group; and a second ligand having a second chain shorter than the first chain and including a thiol group, and a first ratio, defined as a ratio of a molar content of the second ligand to a molar content of the first ligand, among the plurality of ligands bound to the plurality of first quantum dots is greater than a second ratio, defined as a ratio of the molar content of the second ligand to the molar content of the first ligand, among the plurality of ligands bound to the plurality of second quantum dots.

The first chain has 18 or more carbon atoms, and the second chain has 6 to 12 carbon atoms.

The first ligand is oleic acid, and the second ligand is dodecanethiol.

The first ratio is 1 to 2.5.

The second ratio is 0.25 to 1.

The at least one first quantum dot light emitting device may include: a first pixel electrode; a common electrode facing the first pixel electrode; a first light emitting layer between the first pixel electrode and the common electrode and including the plurality of first quantum dots; a hole transfer layer between the first pixel electrode and the first light emitting layer; and an electron transfer layer between the common electrode and the first light emitting layer.

The at least one second quantum dot light emitting device may include: a second pixel electrode; a common electrode facing the second pixel electrode; a second light emitting layer between the second pixel electrode and the common electrode and including the plurality of second quantum dots; a hole transfer layer between the second pixel electrode and the second light emitting layer; and an elextron transfer layer between the common electrode and the second light emitting layer.

A quantum yield (QY) of the first quantum dots may be 90% or more.

A quantum yield (QY) of the second quantum dots is 95% or more.

A photoluminescence (PL) intensity of the second quantum dots, measured after heat treatment at 150 °C for 30 minutes, is 70% or more.

An external quantum efficiency (EQE) of the first quantum dot light emitting device is 13% or more.

An external quantum efficiency (EQE) of the second quantum dot light emitting device is 5% or more.

Each of the plurality of first quantum dots and plurality of second quantum dots has a form including a core and a shell surrounding the core, and the core comprises a III-V group nano semiconductor compound or a II-VI group nano semiconductor compound.

The shell has a stacked structure including a plurality of monolayers, and the stacked structure comprises 10 to 20 monolayers.

In one or more embodiments of the present disclosure, a quantum dot light emitting material may include: a plurality of first quantum dots configured to emit red light upon application of current and a plurality of second quantum dots configured to emit blue light upon application of current; and a plurality of ligands bound to a surface of each of the plurality of first quantum dots and plurality of second quantum dots. The plurality of ligands may include: a first ligand having a first chain and including a carboxyl group; and a second ligand having a second chain shorter than the first chain and including a thiol group. A first ratio, defined as a ratio of the molar content of the second ligand to a molar content of the first ligand, among the plurality of ligands bound to the plurality of first quantum dots is greater than a second ratio, defined as a ratio of a molar content of the second ligand to the molar content of the plurality of first ligand, among the plurality of ligands bound to the second quantum dots.

In one or more embodiments of the present disclosure, a display apparatus may include: a first quantum dot configured to emit light in a first wavelength band, a second quantum dot configured to emit light in a second wavelength band, wherein a plurality of ligands are bound to a surface of each of the first quantum dot and the second quantum dot, the plurality of ligands may include: a first ligand including a first chain having 18 or more carbon atoms and including a carboxyl group; and a second ligand including a second chain having 6 to 12 carbon atoms and including a thiol group; and wherein a first ratio, defined as a molar content of the second ligand relative to a molar content of the first ligand on the first quantum dot, is greater than a second ratio, defined as a molar content of the second ligand relative to a molar content of the first ligand on the second quantum dot.

The first wavelength band of the first quantum dot is 620 nm to 650 nm;

The second wavelength band of the second quantum dot is 450 nm to 480 nm, the first ratio is in a range of 1 to 2.5, and the second ratio is in a range of 0.25 to 1.

The first ligand is oleic acid (OA), the second ligand is dodecanethiol (DDT), and each of the first and second quantum dots may include a core (CR) including a Group III-V compound or a Group II-VI compound, and a shell (SH) including ZnSe, ZnS, or ZnSeS.

A number of carbon atoms in the first chain of the first ligand is at least 6 greater than a number of carbon atoms in the second chain of the second ligand, such that a hole injection path to a quantum dot core is shortened via the second ligand.

The heterogeneous ligand-treated quantum dot technology according to the present disclosure can greatly improve the performance and durability of quantum dot light emitting displays. In particular, by applying ligand ratios optimized for each color, uniform performance improvement can be achieved across full-color displays including quantum dots of various colors.

The effects obtainable by the present disclosure are not limited to the aforementioned effects, and any other effects not mentioned herein will be clearly understood from the following description by those skilled in the art to which the present disclosure pertains.

Although specific embodiments have been illustrated and described above, the present disclosure is not limited to the above embodiments, and various modifications may be made by those skilled in the art to which the present disclosure pertains without departing from the gist of the technical idea described in the following claims.

What is claimed is:

1. A display apparatus comprising:
at least one first quantum dot light emitting device comprising a plurality of first quantum dots configured to emit red light upon application of current; and
at least one second quantum dot light emitting device comprising a plurality of second quantum dots configured to emit blue light upon application of current,
wherein a plurality of ligands are bound to each of the plurality of first quantum dots and the plurality of second quantum dots, and the plurality of ligands comprise:
a first ligand having a first chain and comprising a carboxyl group; and
a second ligand having a second chain shorter than the first chain and comprising a thiol group, and
a first ratio, defined as a ratio of a molar content of the second ligand to a molar content of the first ligand, among the plurality of ligands bound to the plurality of first quantum dots is greater than a second ratio, defined as a ratio of the molar content of the second ligand to the molar content of the first ligand, among the plurality of ligands bound to the plurality of second quantum dots.

2. The display apparatus according to claim 1, wherein the first chain has 18 or more carbon atoms, and the second chain has 6 to 12 carbon atoms.

3. The display apparatus according to claim 2, wherein the first ligand is oleic acid, and the second ligand is dodecanethiol.

4. The display apparatus according to claim 1, wherein the first ratio is 1 to 2.5.

5. The display apparatus according to claim 1, wherein the second ratio is 0.25 to 1.

6. The display apparatus according to claim 1, wherein the first quantum dot light emitting device comprises:
a first pixel electrode;
a common electrode facing the first pixel electrode;
a first light emitting layer between the first pixel electrode and the common electrode and comprising the plurality of first quantum dots;
a hole transfer layer between the first pixel electrode and the first light emitting layer; and
an electron transfer layer between the common electrode and the first light emitting layer.

7. The display apparatus according to claim 1, wherein the second quantum dot light emitting device comprises:
a second pixel electrode;
a common electrode facing the second pixel electrode;
a second light emitting layer between the second pixel electrode and the common electrode and comprising the plurality of second quantum dots;
a hole transfer layer between the second pixel electrode and the second light emitting layer; and
an electron transfer layer between the common electrode and the second light emitting layer.

8. The display apparatus according to claim 1, wherein a quantum yield (QY) of the first quantum dots is 90% or more.

9. The display apparatus according to claim 1, wherein a quantum yield (QY) of the second quantum dots is 95% or more.

10. The display apparatus according to claim 1, wherein a photoluminescence (PL) intensity of the second quantum dots, measured after heat treatment at 150 °C for 30 minutes, is 70% or more.

11. The display apparatus according to claim 1, wherein an external quantum efficiency (EQE) of the first quantum dot light emitting device is 13% or more.

12. The display apparatus according to claim 1, wherein an external quantum efficiency (EQE) of the second quantum dot light emitting device is 5% or more.

13. The display apparatus according to claim 1, wherein each of the plurality of first quantum dots and plurality of second quantum dots has a form including a core and a shell surrounding the core, and
the core comprises a III-V group nano semiconductor compound or a II-VI group nano semiconductor compound.

14. The display apparatus according to claim 13, wherein the shell has a stacked structure comprising a plurality of monolayers, and the stacked structure comprises 10 to 20 monolayers.

15. A quantum dot light emitting material comprising:
a plurality of first quantum dots configured to emit red light upon application of current and a plurality of second quantum dots configured to emit blue light upon application of current; and
a plurality of ligands bound to a surface of each of the plurality of first quantum dots and plurality of second quantum dots,
wherein the plurality of ligands comprise:
a first ligand having a first chain and including a carboxyl group; and
a second ligand having a second chain shorter than the first chain and including a thiol group, and
a first ratio, defined as a ratio of the molar content of the second ligand to a molar content of the first ligand, among the plurality of ligands bound to the plurality of first quantum dots is greater than a second ratio, defined as a ratio of a molar content of the second ligand to the molar content of the first ligand, among the plurality of ligands bound to the second quantum dots.

16. A display apparatus comprising:
a first quantum dot configured to emit light in a first wavelength band,
a second quantum dot configured to emit light in a second wavelength band,
wherein a plurality of ligands are bound to a surface of each of the first quantum dot and the second quantum dot, the plurality of ligands comprising,
a first ligand comprising a first chain having 18 or more carbon atoms and comprising a carboxyl group; and
a second ligand comprising a second chain having 6 to 12 carbon atoms and comprising a thiol group; and
wherein a first ratio, defined as a molar content of the second ligand relative to a molar content of the first ligand on the first quantum dot, is greater than a second ratio, defined as a molar content of the second ligand relative to a molar content of the first ligand on the second quantum dot.

17. The display apparatus of claim 16, wherein
the first wavelength band of the first quantum dot is 620 nm to 650 nm;
the second wavelength band of the second quantum dot is 450 nm to 480 nm;
the first ratio is in a range of 1 to 2.5; and
the second ratio is in a range of 0.25 to 1.

18. The display apparatus of claim 16, wherein
the first ligand is oleic acid (OA);
the second ligand is dodecanethiol (DDT); and
each of the first and second quantum dots comprises a core (CR) including a Group III-V compound or a Group II-VI compound, and a shell (SH) comprising ZnSe, ZnS, or ZnSeS.

19. The display apparatus of claim 16, wherein a number of carbon atoms in the first chain of the first ligand is at least 6 greater than a number of carbon atoms in the second chain of the second ligand, such that a hole injection path to a quantum dot core is shortened via the second ligand.
